(19) United States
(12) Patent Application Publication
(10) Pub. No.: US 2026/0190638 A1
(43) Pub. Date: Jul. 2, 2026

(54) DISPLAY DEVICE, METHOD OF MANUFACTURING DISPLAY DEVICE, AND ELECTRONIC DEVICE

(71) Applicant: Samsung Display Co., Ltd., Yongin-si (KR)

(72) Inventors: A Rong KIM, Yongin-si (KR); Jae Ik KIM, Yongin-si (KR); Young Min MOON, Yongin-si (KR); Hee Jun YANG, Yongin-si (KR); Sa Min LEE, Yongin-si (KR)

(21) Appl. No.: 19/313,707

(22) Filed: Aug. 28, 2025

(30) Foreign Application Priority Data
Dec. 26, 2024 (KR) 10-2024-0197577

(51) Int. Cl. H10K 59/122; H10K 59/12; H10K 59/80

(52) U.S. Cl. CPC H10K 59/122; H10K 59/1201; H10K 59/873

(57) ABSTRACT

A method of manufacturing a display device may include: forming sidewalls in first to third sub-pixel areas; forming anode electrodes on the sidewalls; forming a first emission structure and a first-first cathode electrode in the first to third sub-pixel areas; forming a first-first encapsulation layer on the first-first cathode electrode; removing the first emission structure, the first-first cathode electrode, and the first-first encapsulation layer provided in the second sub-pixel area and the third sub-pixel area; forming a second emission structure and a first-second cathode electrode in the first to third sub-pixel areas; and forming a first-second encapsulation layer on the first-second cathode electrode. The first-second encapsulation layer may be formed discontinuously.

### CROSS-REFERENCE TO RELATED APPLICATION

The present application claims priority to and the benefit of Korean Patent Application No. 10-2024-0197577, filed on Dec. 26, 2024, in the Korean Intellectual Property Office, the entire content of which is hereby incorporated by reference.

### BACKGROUND

### 1. Field

Various embodiments of the present disclosure relate to a display device, a method of manufacturing display device, and an electronic device.

### 2. Description of the Related Art

With the development of information technology, the importance of display devices as a medium which connects users and information has become increasingly emphasized. Accordingly, research and development on display devices have been substantially continuously conducted.

A high-resolution display device and a highly reliable display device may display a clear image. Accordingly, research and development to increase the resolution and reliability of displays have been continuously conducted.

### SUMMARY

An aspect of embodiments of the disclosure is to provide a display device having improved resolution and reliability, and a method of manufacturing the display device.

An aspect of embodiments of the disclosure is to provide an electronic device including the display device having improved resolution and reliability.

Aspects of embodiments of the disclosure are not limited to the above-stated aspects, and those skilled in the art will clearly understand other not mentioned aspects of embodiments are encompassed by the accompanying claims and equivalents thereof.

An embodiment of the disclosure provides a method of manufacturing a display device including: forming sidewalls in first to third sub-pixel areas; forming anode electrodes on the sidewalls; forming a first emission structure and a first-first cathode electrode in the first to third sub-pixel areas; forming a first-first encapsulation layer on the first-first cathode electrode; removing the first emission structure, the first-first cathode electrode, and the first-first encapsulation layer in the second sub-pixel area and the third sub-pixel area; forming a second emission structure and a first-second cathode electrode in the first to third sub-pixel areas; and forming a first-second encapsulation layer on the first-second cathode electrode. The first-second encapsulation layer may be formed discontinuously.

In an embodiment, the first-second encapsulation layer formed in forming the first-second encapsulation layer: may be formed in the first to third sub-pixel areas, and may include an opening.

In an embodiment, the opening may be provided in the first sub-pixel area.

In an embodiment, the first-first encapsulation layer remaining after removal in removing the first-first encapsulation layer: may overlap the first sub-pixel area in a plan view, and may not overlap the second sub-pixel area and the third sub-pixel area in the plan view.

In an embodiment, the opening may be adjacent to an edge of the first-first encapsulation layer remaining after removal in removing the first-first encapsulation layer.

In an embodiment, the opening may surround an edge of the first-first encapsulation layer remaining after removal in removing the first-first encapsulation layer, in the plan view.

In an embodiment, the method may further include removing the second emission structure, the first-second cathode electrode, and the first-second encapsulation layer in the first sub-pixel area and the third sub-pixel area, including providing a first photoresist on the first-second encapsulation layer. At least a portion of the first photoresist may flow into the opening.

In an embodiment, at least the portion of the first photoresist may be under the first-first encapsulation layer in the first sub-pixel area.

In an embodiment, at least the portion of the first photoresist may be in contact with a bottom surface of the first-first encapsulation layer in the first sub-pixel area.

In an embodiment, the method may further include forming a pixel circuit layer on a substrate, including forming a power supply wiring to apply a cathode voltage to the first-first cathode electrode. At least the portion of the first photoresist may be in contact with the power wiring.

In an embodiment, at least one selected from the second emission structure, the first-second cathode electrode, and the first-second encapsulation layer may be removed through dry etching in removing the second emission structure, the first-second cathode electrode, and the first-second encapsulation layer.

In an embodiment, each of the sidewalls may include: a first sidewall; and a second sidewall on the first sidewall and having a larger width than the first sidewall.

In an embodiment, the first sidewall and the second sidewall may include a conductive material (e.g., an electrically conductive material).

In an embodiment, each of the anode electrodes may overlap each of the sidewalls, and the first emission structure may be in contact with a side surface of the second sidewall.

In an embodiment, forming the first-first cathode electrode may include: forming a first cathode electrode; and forming a second cathode electrode on the first cathode electrode. The second cathode electrode may be in contact with a bottom surface of the second sidewall.

An embodiment of the disclosure provides a display device including: a pixel circuit layer on a substrate; a sidewall on the pixel circuit layer; a first light emitting element on the sidewall; and a first-first encapsulation layer on the first light emitting element. The sidewall may have a thickness of 400 nm to 600 nm, and the first-first encapsulation layer may have a thickness of 1.1 μm to 1.6 μm.

In an embodiment, the sidewall may include: a first sidewall; and a second sidewall on the first sidewall and having a larger width than the first sidewall. The first light emitting element may overlap the sidewall in a plan view.

In an embodiment, the first light emitting element may include: an anode electrode on the second sidewall; a first emission structure on the anode electrode; a first cathode electrode on the first emission structure; and a second cathode electrode on the first cathode electrode. The second cathode electrode may be in contact with a bottom surface of the second sidewall.

An embodiment of the disclosure may provide an electronic device including a display device that is manufactured by a method of manufacturing the display device. The method may include forming sidewalls in first to third sub-pixel areas; forming anode electrodes on the sidewalls; forming a first emission structure and a first-first cathode electrode in the first to third sub-pixel areas; forming a first-first encapsulation layer on the first-first cathode electrode; removing the first emission structure, the first-first cathode electrode, and the first-first encapsulation layer in the second sub-pixel area and the third sub-pixel area; forming a second emission structure and a first-second cathode electrode in the first to third sub-pixel areas; and forming a first-second encapsulation layer on the first-second cathode electrode. The first-second encapsulation layer may be formed discontinuously.

In an embodiment, the method may further include: removing the second emission structure, the first-second cathode electrode, and the first-second encapsulation layer in the first sub-pixel area and the third sub-pixel area. The first-second encapsulation layer is formed in forming the first-second encapsulation layer: may be formed in the first to third sub-pixel areas, and may include an opening. Removing the second emission structure, the first-second cathode electrode, and the first-second encapsulation layer may include providing a first photoresist on the first-second encapsulation layer. At least a portion of the first photoresist may flow into the opening.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIG. 1 is a schematic plan view illustrating a display device according to an embodiment.

FIG. 2 is a schematic exploded perspective view illustrating the display device according to an embodiment.

FIG. 3 is a plan view illustrating an embodiment of any one of pixels of FIG. 2.

FIG. 4 is a plan view illustrating another embodiment of any one of the pixels of FIG. 2.

FIG. 5 is a plan view illustrating another embodiment of any one of the pixels of FIG. 2.

FIG. 6 is a schematic cross-sectional view illustrating the display device according to an embodiment.

FIG. 7 is a flowchart illustrating a method of manufacturing the display device according to an embodiment.

FIGS. 8 to 15 are schematic cross-sectional views of the method of manufacturing the display device according to an embodiment.

FIG. 16 is a block diagram of an electronic device according to an embodiment.

FIG. 17 shows schematic views of various suitable embodiments of an electronic device.

### DETAILED DESCRIPTION

As embodiments of the disclosure allow for various suitable changes and numerous embodiments, example embodiments will be illustrated in the drawings and described in more detail in the written description. However, this is not intended to limit the disclosure to particular modes of practice, and it is to be appreciated that all suitable changes, equivalents, and substitutes that do not depart from the spirit and technical scope of the disclosure are encompassed in the disclosure.

It will be understood that, although the terms “first”, “second”, and the like may be used herein to describe various suitable elements, these elements should not be limited by these terms. These terms are only used to distinguish one element from another element. For instance, a first element discussed below could be termed a second element without departing from the teachings of the disclosure. Similarly, the second element could also be termed the first element. In the present disclosure, the singular forms are intended to include the plural forms as well, unless the context clearly indicates otherwise.

It will be further understood that the terms “comprise”, “include”, “have”, and the like when used in the present disclosure, specify the presence of stated features, integers, steps, operations, elements, components, and/or combinations of them but do not preclude the presence or addition of one or more other features, integers, steps, operations, elements, components, and/or combinations thereof. Furthermore, in embodiments where a first part, such as a layer, a film, a region, or a plate, is placed on a second part, the first part may be not only directly on the second part but a third part may intervene between them. In embodiments, where it is expressed that a first part, such as a layer, a film, a region, or a plate, is formed on a second part, the surface of the second part on which the first part is formed is not limited to an top surface of the second part but may include other surfaces, such as a side surface or a bottom surface of the second part. To the contrary, in case that a first part, such as a layer, a film, a region, or a plate, is described as being “under” a second part, this includes not only embodiments where the first part is directly under the second part but also embodiments where a third part is interposed between the first part and the second part.

Various embodiments of the disclosure relate to a display device, a method of manufacturing display device, and an electronic device. Hereinafter, a display device, a method of manufacturing display device, and an electronic device in accordance with embodiments will be described with reference to the attached drawings.

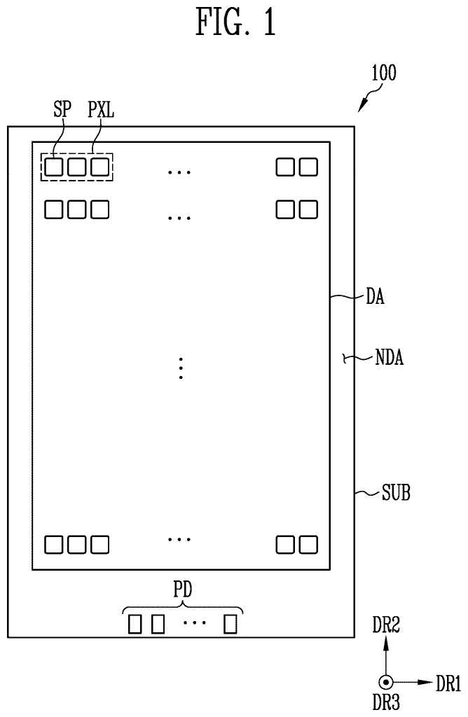

FIG. 1 is a schematic plan view illustrating a display device in accordance with an embodiment.

Referring to FIG. 1, the display device 100 in accordance with an embodiment is configured to emit light.

The display device 100 may include a display area DA and a non-display area NDA. The display device 100 may display an image through the display area DA. The non-display area NDA may be around the display area DA.

The display device 100 may include a substrate SUB, sub-pixels SP, and pads PD.

The display device 100 may be applied to various suitable fields. For example, the display device 100 may be used as a display screen of a device, such as a head-mounted display (HMD), a virtual reality (VR) device, a mixed reality (MR) device, and/or an augmented reality (AR) device. In embodiments, the display device 100 may be provided very close to eyes of a user. In embodiments, relatively high-density sub-pixels SP may be required or utilized. To increase the pixel density of the sub-pixels SP, the substrate SUB may be provided using a silicon substrate. The sub-pixels SP and/or the display device 100 may be on the substrate SUB, which is a silicon substrate.

The sub-pixels SP may be in the display area DA on the substrate SUB. The sub-pixels SP may be provided in a matrix form in a first direction DR1 and a second direction DR2 crossing the first direction DR1. However, the embodiments are not limited to the aforementioned example. For example, the sub-pixels SP may be provided in a zigzag pattern in the first direction DR1 and the second direction DR2. For example, the sub-pixels SP may be provided in a PENTILE® arrangement structure (e.g., an RGBG matrix, RGBG structure, or RGBG matrix structure), but the present disclosure is not limited thereto. PENTILE® is a duly registered trademark of Samsung Display Co., Ltd. The first direction DR1 may refer to a row direction, and the second direction DR2 may refer to a column direction. A third direction DR3 may be perpendicular (e.g., substantially perpendicular) to the first direction DR1 and the second direction DR2 and, depending on the embodiment, may correspond to a thickness direction of the substrate SUB or a light output direction of the display device 100.

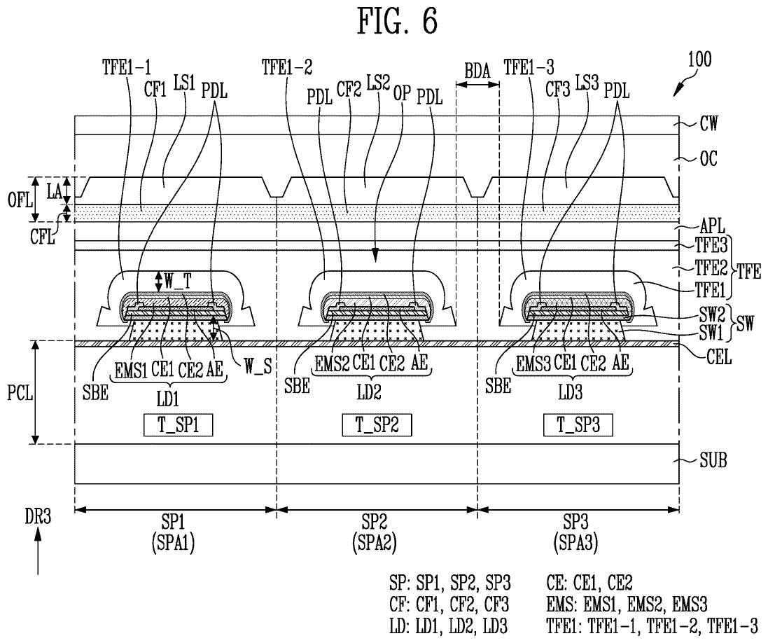

Each of the sub-pixels SP may include at least one light emitting element LD (refer to FIG. 6) configured to generate light. Accordingly, each of the sub-pixels SP may generate light in a set or specific color such as red, green, blue, cyan, magenta, or yellow. Two or more sub-pixels SP among the sub-pixels SP may form one pixel PXL. For example, as illustrated in FIG. 1, three sub-pixels SP may form one pixel PXL.

Hereinafter, descriptions will be provided based on an embodiment where the sub-pixels SP include a first sub-pixel SP1 which provides light of a first color (e.g., red), a second sub-pixel SP2 which provides light of a second color (e.g., green), and a third sub-pixel SP3 which provides light of a third color (e.g., blue).

In an embodiment, the first sub-pixel SP1, as a red pixel, may provide light in a wavelength band in a range from 600 nm to 750 nm. The second sub-pixel SP2, as a green pixel, may provide light in a wavelength band in a range from 480 nm to 560 nm. The third sub-pixel SP3, as a blue pixel, may provide light in a wavelength band in a range from 370 nm to 460 nm. However, the disclosure is not limited thereto, and the first sub-pixel SP1 may be a blue pixel, the second sub-pixel SP2 may be a green pixel, and the third sub-pixel SP3 may be a red pixel.

Components to control the sub-pixels SP may be provided in the non-display area NDA on the substrate SUB. For example, wirings connected to the sub-pixels SP (e.g., gate lines and data lines for driving the sub-pixels SP) may be provided in the non-display area NDA. Furthermore, a gate driver, a data driver, a voltage generator, a controller, a temperature sensor, and/or the like may be integrated in the non-display area NDA of the display device 100 to acquire driving signals to be supplied to the sub-pixels SP. However, the disclosure is not limited to the aforementioned example.

The pads PD may be provided in the non-display area NDA on the substrate SUB. The pads PD may be electrically connected to the sub-pixels SP through the wirings. For example, the pads PD may be connected to the sub-pixels SP through the data lines.

The pads PD may interface the components in the display area DA and the non-display area NDA with other components of the display device 100. In embodiments, voltages and signals required or useful for the operation of the components included in the display device 100 may be provided from a driver integrated circuit through the pads PD. For example, the data lines may be electrically connected to the driver integrated circuit through the pads PD. For example, the power voltages for driving the sub-pixels SP may be received from the driver integrated circuit through the pads PD. For example, a gate control signal to control the gate driver may be transmitted from the driver integrated circuit to the gate driver through the pads PD.

In embodiments, a circuit board may be electrically connected to the pads PD by a conductive adhesive component (e.g., an electrically conductive adhesive component) such as an anisotropic conductive film (e.g., an anisotropic electrically conductive film). In embodiments, the circuit board may be a flexible circuit board or flexible film that is made of flexible material. The driver integrated circuit may be mounted on the circuit board and be electrically connected to the pads PD.

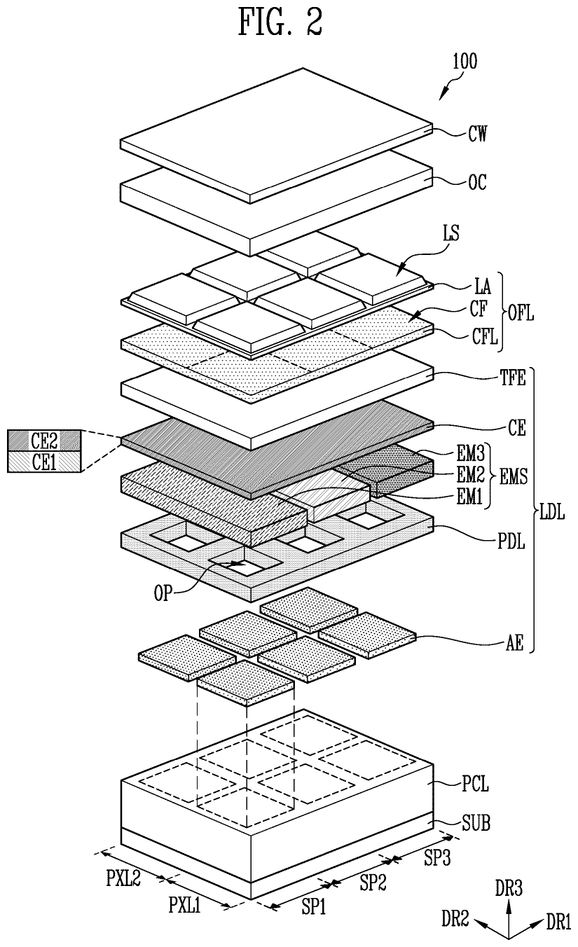

FIG. 2 is a schematic exploded perspective view illustrating the display device in accordance with an embodiment. In FIG. 2, for the sake of clear and concise explanation, there is schematically illustrated a portion of the display device 100 corresponding to two pixels PXL1 and PXL2 among the pixels PXL. The remaining portions of the display device 100 corresponding to the other pixels may also be configured in the same or substantially the same manner.

Referring to FIG. 2, each of the first and second pixels PXL1 and PXL2 may include first to third sub-pixels SP1 to SP3. However, the embodiments are not limited to the aforementioned example. For example, each of the first and second pixels PXL1 and PXL2 may include four sub-pixels, or may include two sub-pixels.

In FIG. 2, there is illustrated an embodiment where the first to third sub-pixels SP1 to SP3 have rectangular shapes and an identical or substantially identical size when viewed in the third direction DR3 crossing the first and second directions DR1 and DR2. However, the embodiments are not limited to the aforementioned example. The first to third sub-pixels SP1 to SP3 may be modified to have various suitable shapes.

The display device 100 may include a substrate SUB, a pixel circuit layer PCL, a light-emitting-element layer LDL, an encapsulation layer TFE, an optical functional layer OFL, an overcoat layer OC, and a cover window CW.

In embodiments, the substrate SUB may include a silicon wafer substrate formed through a semiconductor process. The substrate SUB may include semiconductor material suitable to form circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, and/or the like. In embodiments, the substrate SUB may include a glass substrate. In embodiments, the substrate SUB may include a polyimide (PI) substrate.

The pixel circuit layer PCL may be on the substrate SUB. The substrate SUB and/or the pixel circuit layer PCL may include insulating layers (e.g., electrically insulating layer), and conductive patterns (and electrically conductive patterns) between the insulating layers. The conductive patterns of the pixel circuit layer PCL may function as at least portions of the circuit components, wirings, and/or the like. The conductive patterns may include various suitable conductive materials (e.g., electrically conductive materials). The embodiments are not limited to a specific example. The circuit elements may include respective sub-pixel circuits of the first to third sub-pixels SP1 to SP3. The sub-pixel circuits may each include transistors and one or more capacitors.

The light-emitting-element layer LDL may include anode electrodes AE, a pixel defining layer PDL, an emission structure EMS, and a cathode electrode CE.

The anode electrodes AE may be on the pixel circuit layer PCL. The anode electrodes AE may be electrically connected to circuit elements of the pixel circuit layer PCL.

The pixel defining layer PDL may be provided on the anode electrodes AE. The pixel defining layer PDL may define, therein, openings OP that expose respective portions of the anode electrodes AE. The pixel defining layer PDL may enclose respective edges of the anode electrodes AE, and allows respective portions of the anode electrodes AE to be exposed. The openings OP defined in the pixel defining layer PDL may be understood as respective emission areas corresponding to the first to third sub-pixels SP1 to SP3.

In embodiments, the pixel defining layer PDL may include inorganic material. In embodiments, the pixel defining layer PDL may include a plurality of inorganic layers stacked on top of one another. For example, the pixel defining layer PDL may include silicon oxide (SiOₓ) and silicon nitride (SiNₓ). However, the material of the pixel defining layer PDL is not limited to the aforementioned examples. In an embodiment, the pixel defining layer PDL may include organic material.

The emission structure EMS may be on the anode electrodes AE that are exposed through the openings OP defined in the pixel defining layer PDL. The emission structure EMS may include an emission layer configured to generate light, an electron transport component configured to transport electrons, and a hole transport component configured to transport holes.

In embodiments, the emission structure EMS may be charged into the openings OP defined in the pixel defining layer PDL, and may be disconnected or bent at boundaries between the first to third sub-pixels SP1 to SP3.

The emission structure EMS may include first to third emission structures EMS1 to EMS3 which are spaced apart from each other and respectively form the first to third sub-pixels SP1 to SP3. For example, the first sub-pixel SP1 may include the first emission structure EMS1. The second sub-pixel SP2 may include the second emission structure EMS2. The third sub-pixel SP3 may include the third emission structure EMS3. The first emission structure EMS1, the second emission structure EMS2, and the third emission structure EMS3 may be formed through different deposition processes.

The cathode electrode CE may be on the emission structure EMS.

The cathode electrode CE may be a thin metal layer having a thickness that allows light emitted from the emission structure EMS to pass through cathode electrode CE.

The cathode electrode CE may include a multilayer structure. For example, the cathode electrode CE may include a first cathode electrode CE1 and a second cathode electrode CE2.

The first cathode electrode CE1 may be directly adjacent to the emission structure EMS (e.g., a top surface of the emission structure EMS may be in contact with a bottom surface of the first cathode electrode CE1), and may supply a cathode voltage to the emission structure EMS.

In an embodiment, the first cathode electrode CE1 may include a conductive material (e.g., an electrically conductive material). For example, the first cathode electrode CE1 may include at least one selected from silver (Ag), magnesium (Mg), aluminum (Al), and copper (Cu).

The second cathode electrode CE2 may be provided on the first cathode electrode CE1. A bottom surface of the second cathode electrode CE2 may be in contact with a top surface of the first cathode electrode CE1. The second cathode electrode CE2 may be electrically connected to a wiring which applies a cathode voltage to the second cathode electrode CE2.

The second cathode electrode CE2 may include transparent conductive material (e.g., transparent electrically conductive material). For example, the second cathode electrode CE2 may include transparent conductive oxide (TCO; e.g., transparent electrically conductive oxide). For example, the second cathode electrode CE2 may include one or more selected from the group consisting of indium zinc oxide (IZO), indium oxide (IO), tin oxide (TO), indium tin oxide (ITO), indium gallium zinc oxide (IGZO), aluminum zinc oxide (AZO), aluminum tin oxide (ATO), indium tin zinc oxide (ITZO), zinc oxide (ZnO), and tin oxide (SnO₂). For example, the second cathode electrode CE2 may include IZO.

In an embodiment, as the second cathode electrode CE2 is provided on the first cathode electrode CE1, the risk of a cathode connection path being interrupted may be reduced.

Any one selected from the anode electrodes AE, a portion of the emission structure EMS that overlap the any one of the anode electrodes AE, and a portion of the cathode electrode CE that overlaps the portion of the emission structure EMS can be understood as constituting one light emitting element LD. In embodiments, each of the light emitting elements of the first to third sub-pixels SP1 to SP3 may include one anode electrode AE, a portion of the emission structure EMS that overlaps the one anode electrode AE, and a portion of the cathode electrode CE that overlaps the portion of the emission structure EMS. In each of the first to third sub-pixels SP1 to SP3, holes injected from the anode electrode AE and electrons injected from the cathode electrode CE are transported into the emission layer of the emission structure EMS, thus forming excitons. When the excitons make a transition from an excited state to a ground state, light can be generated. The luminance of light may be determined based on the amount of current flowing through the emission layer. Depending on the configuration of the emission layer, the wavelength range of the generated light may be determined.

The encapsulation layer TFE may be provided on the cathode electrode CE. The encapsulation layer TFE may cover the light-emitting-element layer LDL, and the pixel circuit layer PCL. The encapsulation layer TFE may prevent or reduce penetration of oxygen, moisture, and/or the like into the light-emitting-element layer LDL. In embodiments, the encapsulation layer TFE may include a structure formed by alternately stacking one or more inorganic layers and one or more organic layers. For example, the inorganic layer may include, for example, silicon nitride, silicon oxide, and/or silicon oxynitride. For example, the organic layer may include organic insulating material (e.g., organic electrically insulating material), such as acrylic resin, epoxy resin, phenol resin, polyamide resin, polyimide resin, unsaturated polyester resin, polyphenylenether resin, polyphenylenesulfide resin, and/or benzocyclobutene (BCB). However, the materials of the organic layer and the inorganic layer of the encapsulation layer TFE are not limited to the aforementioned examples.

The optical functional layer OFL may be provided on the encapsulation layer TFE. The optical functional layer OFL may include a color filter layer CFL and a lens array LA.

The color filter layer CFL may be between the encapsulation layer TFE and the lens array LA. The color filter layer CFL may filter light emitted from the emission structure EMS and selectively output light in a wavelength range or color corresponding to each sub-pixel. The color filter layer CFL may include color filters CF which respectively correspond to the first to third sub-pixels SP1 to SP3. Each of the color filters CF may transmit light within a wavelength range corresponding to the related sub-pixel. For example, the color filter that corresponds to the first sub-pixel SP1 may transmit light in a red color, the color filter that corresponds to the second sub-pixel SP2 may transmit light in a green color, and the color filter that corresponds to the third sub-pixel SP3 may transmit light in a blue color. Depending on the light emitted from the emission structure EMS of each sub-pixel, at least some of the color filters CF may be omitted.

The lens array LA may be provided on the color filter layer CFL. The lens array LA may include lenses LS that respectively correspond to the first to third sub-pixels SP1 to SP3. Each of the lenses LS may output and direct light emitted from the emission structure EMS along an intended path, thus enhancing the light output efficiency. The lens array LA may have a relatively high refractive index. For example, the lens array LA may have a higher refractive index than the overcoat layer OC. In embodiments, the lenses LS may include organic material. In embodiments, the lenses LS may include acrylic material. However, the material of the lenses LS is not limited to the foregoing examples.

The overcoat layer OC may be provided on the lens array LA. The overcoat layer OC may cover the optical functional layer OFL, the encapsulation layer TFE, the emission structure EMS, and/or the pixel circuit layer PCL. The overcoat layer OC may include various materials suitable to protect underlying layers from foreign substances, such as dust, moisture, and/or the like. For example, the overcoat layer OC may include at least one of an inorganic insulating layer (e.g., an inorganic electrically insulating layer) or an organic insulating layer (e.g., an organic electrically insulating layer). For example, the overcoat layer OC may include epoxy, but embodiments are not limited thereto. The overcoat layer OC may have a lower refractive index than the lens array LA.

The cover window CW may be provided on the overcoat layer OC. The cover window CW may protect underlying layers. The cover window CW may have a higher refractive index than the overcoat layer OC. The cover window CW may include glass, but embodiments are not limited thereto. For example, the cover window CW may be an encapsulation glass layer configured to protect components located thereunder. In other embodiments, the cover window CW may be omitted.

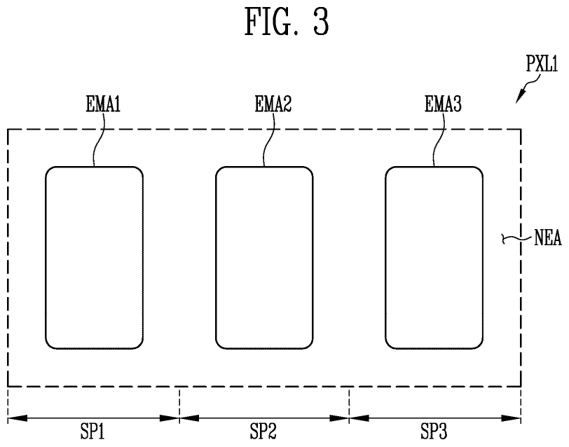

FIG. 3 is a plan view illustrating an embodiment of any one of the pixels of FIG. 2. In FIG. 3, for the sake of clear and concise explanation, the first pixel PXL1 of FIG. 2 is schematically depicted as a representative example of the first pixel PXL1 and the second pixel PXL2. The other pixels may be configured in the same or substantially the same manner as the first pixel PXL1.

Referring to FIGS. 2 and 3, the first pixel PXL1 may include a first sub-pixel SP1, a second sub-pixel SP2, and a third sub-pixel SP3 which are provided in the first direction DR1.

The first sub-pixel SP1 may include a first emission area EMA1 and a non-emission area NEA around the first emission area EMA1. The second sub-pixel SP2 may include a second emission area EMA2 and a non-emission area NEA around the second emission area EMA2. The third sub-pixel SP3 may include a third emission area EMA3 and a non-emission area NEA around the third emission area EMA3.

The first emission area EMA1 may be an area where light is emitted from a portion of the emission structure EMS (e.g., from the first emission structure EMS1) that corresponds to the first sub-pixel SPX1. The second emission area EMA2 may be an area where light is emitted from a portion of the emission structure EMS (e.g., from the second emission structure EMS2) that corresponds to the second sub-pixel SP2. The third emission area EMA3 may be an area where light is emitted from a portion of the emission structure EMS (e.g., from the third emission structure EMS3) that corresponds to the third sub-pixel SP3. As described with reference to FIG. 2, the emission areas may be understood as the respective openings OP of the pixel defining layer PDL that correspond to the first sub-pixel SP1, the second sub-pixel SP2, and the third sub-pixel SP3.

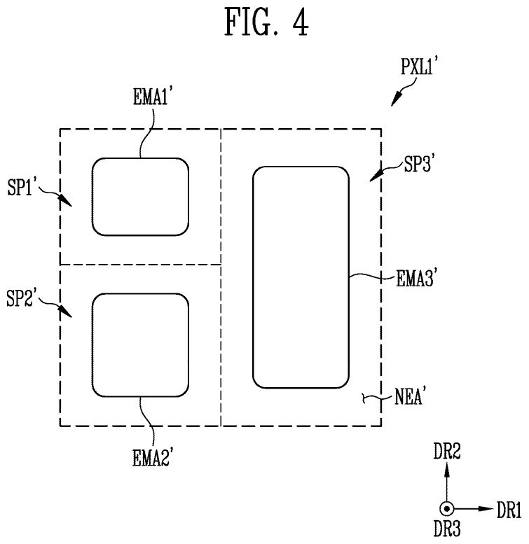

FIG. 4 is a plan view illustrating another embodiment of any one of the pixels of FIG. 2.

Referring to FIG. 4, a first pixel PXL1′ may include first to third sub-pixels SP1′ to SP3′.

The first sub-pixel SP1′ may include a first emission area EMA1′ and a non-emission area NEA′ around the first emission area EMA1′. The second sub-pixel SP2′ may include a second emission area EMA2′ and a non-emission area NEA′ around the second emission area EMA2′. The third sub-pixel SP3′ may include a third emission area EMA3′ and a non-emission area NEA′ around the third emission area EMA3′.

The first sub-pixel SP1′ and the second sub-pixel SP2′ may be provided in the second direction DR2. The third sub-pixel SP3′ may be provided in the first direction DR1 with respect to each of the first and second sub-pixels SP1′ and SP2′.

The second sub-pixel SP2′ may have a larger surface area than the first sub-pixel SP1′. The third sub-pixel SP3′ may have a larger surface area than the second sub-pixel SP2′. Therefore, the second emission area EMA2′ may have a larger surface area than the first emission area EMA1′. The third emission area EMA3′ may have a larger surface area than the second emission area EMA2′. However, the embodiments are not limited to the aforementioned example. For example, the first and second sub-pixels SP1′ and SP2′ may have substantially an identical surface area. The third sub-pixel SP3′ may have a larger surface area than each of the first and second sub-pixels SP1′ and SP2′. As such, the surface areas of the first to third sub-pixels SP1′ to SP3′ may be changed in various suitable ways depending on the embodiments.

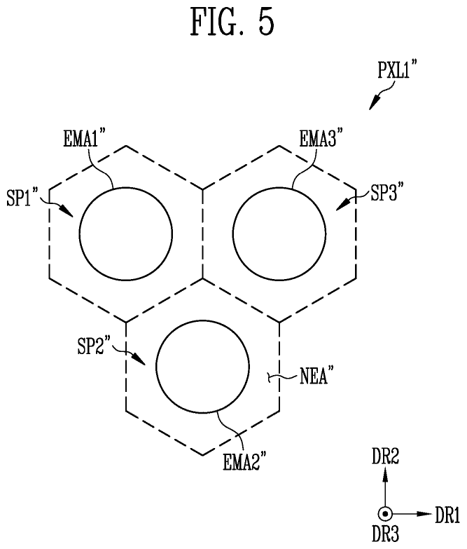

FIG. 5 is a plan view illustrating another embodiment of any one of the pixels of FIG. 2.

Referring to FIG. 5, a first sub-pixel SP1″ may include a first emission area EMA1″ and a non-emission area NEA″ around the first emission area EMA1″. A second sub-pixel SP2″ may include a second emission area EMA2″ and a non-emission area NEA″ around the second emission area EMA2″. A third sub-pixel SP3″ may include a third emission area EMA3″ and a non-emission area NEA″ around the third emission area EMA3″.

Each of the first to third sub-pixels SP1″ to SP3″ may have a polygonal shape in the third direction DR3. For example, the shapes of the first to third sub-pixels SP1″ to SP3″ may be hexagonal, as illustrated in FIG. 5.

Each of the first to third emission areas EMA1″ to EMA3″ may have a circular shape (e.g., a generally circular shape) in the third direction DR3. However, the embodiments are not limited to the aforementioned example. For example, each of the first to third emission areas EMA1″ to EMA3″ may have a polygonal shape.

The first and third sub-pixels SP1″ and SP3″ may be provided in the first direction DR1. The second sub-pixel SP2″ may be provided in a direction (or a diagonal direction) inclined at an acute angle relative to the second direction DR2 with respect to the first sub-pixel SP1″.

The arrangements of the sub-pixels illustrated in FIGS. 3 to 5 are illustrative, and embodiments are not limited thereto. Each pixel PXL may include two or more sub-pixels SP. The sub-pixels SP may be provided in various suitable ways. Each of the sub-pixels SP may have various suitable shapes, and each of the emission areas EMA1, EMA2, and EMA3 of the sub-pixels SP may have various suitable shapes.

In embodiments, an area in which the first sub-pixel SP1 is defined (or an area in which the first sub-pixel SP1 is provided) may be defined as a first sub-pixel area SPA1 (see FIG. 6), an area in which the second sub-pixel SP2 is defined (or an area in which the second sub-pixel SP2 is provided) may be defined as a second sub-pixel area SPA2 (see FIG. 6), and an area in which the third sub-pixel SP3 is defined (or an area in which third sub-pixel SP3 is provided) may be defined as a third sub-pixel area SPA3 (see FIG. 6).

FIG. 6 is a schematic sectional view illustrating the display device in accordance with an embodiment. FIG. 6 schematically illustrates the first to third sub-pixels SP1 to SP3.

Referring to FIG. 6, the substrate SUB and the pixel circuit layer PCL provided on the substrate SUB may be provided.

The pixel circuit layer PCL may be provided on the substrate SUB. The substrate SUB and the pixel circuit layer PCL may include respective circuit elements of the first to third sub-pixels SP1 to SP3. For example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3.

In an embodiment, the pixel circuit layer PCL may include a via layer which has an overall flat surface and a metal layer CEL on the via layer.

The via layer may planarize stepped portions of components under the via layer. The via layer may include at least one of silicon oxide (SiOₓ), silicon nitride (SiNₓ), or silicon carbon nitride (SiCN), but embodiments are not limited thereto.

The metal layer CEL may be a power supply wiring (e.g., an ELVSS power supply wiring) that transmits a cathode voltage to the cathode electrode CE. The metal layer CEL may include a conductive material (e.g., an electrically conductive material). For example, the metal layer CEL may include at least one selected from aluminum (Al), molybdenum (Mo), copper (Cu), and silver (Ag).

In embodiments, a planarization layer and first to third reflective electrodes may further be between the via layer and the metal layer CEL. In an embodiment, the first to third sub-pixels SP1 to SP3 may respectively include first to third reflective electrodes. The first to third reflective electrodes may be respectively provided in first to third sub-pixel areas SPA1 to SPA3 in which the first to third sub-pixels SP1 to SP3 are respectively defined (or provided). The first to third reflective electrodes may be provided on the via layer, and may function as full mirrors which reflect light emitted from the emission structure EMS toward a display surface (or the cover window CW). The planarization layer may be provided on the first to third reflective electrodes. The planarization layer may cover overall surfaces of the first to third reflective electrodes and the via layer, and may have a flat surface.

The light-emitting-element layer LDL may be provided on the pixel circuit layer PCL. The light-emitting-element layer LDL may include sidewalls SW, a sub-insulating layer SBE, anode electrodes AE, the pixel defining layer PDL, the emission structure EMS, the cathode electrode CE, and the encapsulation layer TFE.

The sidewalls SW may be on the metal layer CEL. The sidewalls SW may be in contact with the metal layer CEL. Each of the sidewalls SW may be provided in each of the first to third sub-pixel areas SPA1 to SPA3. In combination with FIG. 3, the sidewall SW may overlap the first to third emission areas EMA1 to EMA3 in a plan view.

Each of the sidewalls SW may include a first sidewall SW1 and a second sidewall SW2 provided on the first sidewall SW1. The first sidewall SW1 may form a base on which the second sidewall SW2 is provided. The second sidewall SW2 may have a width larger than that of the first sidewall SW1, thereby forming a tip which protrudes in a planar direction in which the substrate SUB is provided. For example, each of the sidewalls SW may have a “T”-shaped structure or an undercut structure having the second sidewall SW2 protrude further than the first sidewall SW1.

In an embodiment, side surfaces of the first sidewall SW1 and the second sidewall SW2 may be inclined. However, the disclosure is not limited thereto, and in an embodiment, the side surfaces of the first sidewall SW1 and the second sidewall SW2 may be flat.

Each of the first sidewall SW1 and the second sidewall SW2 may include conductive material (e.g., electrically conductive material). At least a portion of the sidewall SW may be electrically connected to the cathode electrode CE, thus forming an electrical cathode connection path. For example, the cathode electrode CE (e.g., the second cathode electrode CE2) may be in contact with a bottom surface of the second sidewall SW2 and may be electrically connected to the second sidewall SW2. The second sidewall SW2 may be electrically connected to the metal layer CEL, and the second cathode electrode CE2 may be electrically connected to the second sidewall SW2, and may receive a cathode voltage from the metal layer CEL.

In an embodiment, the sidewall SW may have a thickness W_S of 400 nm to 600 nm. The thickness W_S of the sidewall SW is defined as the sum of the thickness of the first sidewall SW1 and the thickness of the second sidewall SW2, and the thickness may be defined in the third direction DR3.

The sub-insulating layer SBE may be on the second sidewall SW2. The sub-insulating layer SBE may overlap the second sidewall SW2 in a plan view. The sub-insulating layer SBE may be in contact with the second sidewall SW2. The sub-insulating layer SBE may be between the second sidewall SW2 and each of the anode electrodes AE to insulate (e.g., electrically insulate) between the second sidewall SW2 and the anode electrode AE.

The sub-insulating layer SBE may include an insulating material (e.g., an electrically insulating material). For example, the sub-insulating layer SBE may include at least one selected from silicon oxide (SiOx) and silicon nitride (SiNx). However, the disclosure is not limited thereto, and the sub-insulating layer SBE may include various suitable insulating materials (e.g., electrically insulating materials).

The anode electrode AE may be on the sub-insulating layer SBE. For example, the anode electrode AE may be on each of the sub-insulating layers SBE that overlap each of the first to third sub-pixels SP1 to SP3. The anode electrode AE may be provided at a higher position than the sidewall SW. For example, the distance of the anode electrode AE is spaced from the metal layer CEL may be greater than the distance of the second sidewall SW2 is spaced from metal layer CEL.

The anode electrode AE may overlap the second sidewall SW2 in a plan view. In a plan view, the area of each of the anode electrodes AE may be smaller than the area of the second sidewall SW2. Each of the anode electrodes AE may have an end that does not coincide with the second sidewall SW2 in a plan view.

In an embodiment, the anode electrode AE may include at least one selected from transparent conductive materials, such as indium tin oxide (ITO), indium zinc oxide (IZO), zinc oxide (ZnOₓ), indium gallium zinc oxide (IGZO), and indium tin zinc oxide (ITZO). However, the material of the anode electrode AE is not limited to the aforementioned example. For example, the anode electrode AE may include titanium nitride.

Each of the pixel defining layers PDL may be provided on the anode electrode AE. For example, the pixel defining layer PDL may enclose respective edges of the anode electrode AE while allowing at least respective portions of the anode electrode AE to be exposed. The pixel defining layer PDL may be on the sidewall SW (e.g., the second sidewall SW2). The pixel defining layer PDL may be provided at a position higher than the sidewall SW. For example, the distance of the pixel defining layer PDL spaced from the metal layer CEL may be greater than the distance of the second sidewall SW2 spaced from the metal layer CEL.

Each of the first to third emission structures EMS1 to EMS3 may have an area greater than that of the second sidewall SW2 in a plan view. For example, each of the first to third emission structures EMS1 to EMS3 may entirely overlap the second sidewall SW2 and enclose the pixel defining layer PDL and the second sidewall SW2. For example, each of the first to third emission structures EMS1 to EMS3 may be in contact with the side surfaces of the pixel defining layer PDL and the second sidewall SW2.

In an embodiment, the first to third emission structures EMS1 to EMS3 may respectively form first to third light emitting elements LD1 to LD3 on the sidewall SW. Each of the first to third emission structures EMS1 to EMS3 may be provided on the sidewall SW to overlap the sidewall SW. Each of first to third light emitting elements LD1 to LD3 may be provided on the sidewall SW to overlap the sidewall SW, thereby preventing a shadow effect during a process of depositing the first to third emission structures EMS1 to EMS3, and enhancing the resolution of the display device 100.

The first cathode electrode CE1 may be on each of the first to third emission structures EMS1 to EMS3. The second cathode electrode CE2 may be on the first cathode electrode CE1. A first surface (e.g., bottom surface) of the first cathode electrode CE1 may be in contact with each of the first to third emission structures EMS1, EMS2, EMS3, and a second surface (e. g., top surface) of the first cathode electrode CE1 is in contact with the second cathode electrode CE2. A first surface (e.g., bottom surface) of the second cathode electrode CE2 may be in contact with the first cathode electrode CE1. The second cathode electrode CE2 may extend to enclose the first cathode electrode CE1 and the sidewall SW (e.g., the second sidewall SW2). For example, the second cathode electrode CE2 may extend to contact with the bottom surface of the second sidewall SW2.

The anode electrode AE provided in the first sub-pixel area SPA1, a first emission structure EMS1 that overlaps the anode electrode AE, and a portion of the cathode electrode CE that overlaps the first emission structure EMS1 may constitute the first light emitting element LD1. The anode electrode AE provided in the second sub-pixel area SPA2, the second emission structure EMS2 that overlaps the anode electrode AE, and a portion of the cathode electrode CE that overlaps the second emission structure EMS2 may constitute the second light emitting element LD2. The anode electrode AE provided in the third sub-pixel area SPA3, a third emission structure EMS3 that overlaps the anode electrode AE, and a portion of the cathode electrode CE that overlaps the third emission structure EMS3 may constitute the third light emitting element LD3.

The first light emitting element LD1 may be on the sidewall SW of the first sub-pixel area SPA1 to overlap the sidewall SW of the first sub-pixel area SPA1. The second light emitting element LD2 may be on the sidewall SW of the second sub-pixel area SPA2 to overlap the sidewall SW of the second sub-pixel area SPA2. The third light emitting element LD3 may be on the sidewall SW of the third sub-pixel area SPA3 to overlap the sidewall SW of the third sub-pixel area SPA3.

The encapsulation layer TFE is on the light emitting element LD. The encapsulation layer TFE may be in contact with the light emitting device LD. The encapsulation layer TFE may prevent penetration of oxygen, moisture, and/or the like into the light emitting element LD and the pixel circuit layer PCL.

In an embodiment, the encapsulation layer TFE may include first to third encapsulation layers TFE1 to TFE3. In an embodiment, the first encapsulation layer TFE1 may include an organic layer, the second encapsulation layer TFE2 may include an inorganic layer, and the third encapsulation layer TFE3 may include an organic layer. However, the disclosure is not limited thereto, and the first encapsulation layer TFE1 may include an inorganic layer, the second encapsulation layer TFE2 may include an organic layer, and the third encapsulation layer TFE3 may include an inorganic layer.

The first encapsulation layer TFE1 may include a first-first encapsulation layer TFE 1-1 provided in the first sub-pixel area SPA1, a first-second encapsulation layer TFE1-2 provided in the second sub-pixel area SPA2, and a first-third encapsulation layer TFE1-3 provided in the third sub-pixel area SPA3. The first-first encapsulation layer TFE1-1, the first-second encapsulation layer TFE1-2, and the first-third encapsulation layer TFE1-3 may be formed in different processes. Each of the first-first encapsulation layer TFE1-1, the first-second encapsulation layer TFE1-2, and the first-third encapsulation layer TFE1-3 may be spaced apart from each other.

The top surface of each of the first-first encapsulation layer TFE1-1, the first-second encapsulation layer TFE1-2, and the first-third encapsulation layer TFE1-3 may have a step. For example, the top surface of each of the first-first encapsulation layer TFE1-1, the first-second encapsulation layer TFE1-2, and the first-third encapsulation layer TFE1-3 may be at a different height in a region that overlaps with the sidewall SW compared to a region that does not overlap with the sidewall SW. For example, the top surface of each of the first-first encapsulation layer TFE1-1, the first-second encapsulation layer TFE1-2, and the first-third encapsulation layer TFE1-3 may have a convex shape in a cross section.

In an embodiment, each of the first-first encapsulation layer TFE1-1, the first-second encapsulation layer TFE1-2, and the first-third encapsulation layer TFE1-3 may have a thickness W_T of 1.1 μm to 1.6 μm.

The first encapsulation layer TFE1 may passivate at least a portion of the light emitting elements LD and the sidewalls SW, and the second and third encapsulation layers TFE2 and TFE3 may be sequentially on the first encapsulation layer TFE1. However, the disclosure is not limited thereto, and in an embodiment, the encapsulation layer TFE may be formed as a single layer consisting of only the first encapsulation layer TFE1.

The optical functional layer OFL may be provided on the encapsulation layer TFE. In embodiments, the optical functional layer OFL may be attached to the encapsulation layer TFE through an adhesive layer APL. For example, the optical functional layer OFL may be fabricated through a separate process and attached to the encapsulation layer TFE by the adhesive layer APL. The adhesive layer APL may further perform a function of protecting underlying layers including the encapsulation layer TFE.

The optical functional layer OFL may include a color filter layer CFL and a lens array LA. The color filter layer CFL may include first to third color filters CF1 to CF3 which respectively correspond to the first to third sub-pixels SP1 to SP3. The first to third color filters CF1 to CF3 may transmit light in different wavelength ranges. For example, the first to third color filters CF1 to CF3 may respectively transmit red light, green light, and blue light.

In embodiments, the first to third color filters CF1 to CF3 may partially overlap each other in the boundary area BDA. In other embodiments, the first to third color filters CF1 to CF3 may be spaced apart from each other, and a black matrix may be provided between the first to third color filters CF1 to CF3.

The lens array LA may be provided on the color filter layer CFL. The lens array LA may include first to third lenses LS1 to LS3 which respectively correspond to the first to third sub-pixels SP1 to SP3. The first to third lenses LS1 to LS3 may respectively direct light emitted from the first to third light emitting elements LD1 to LD3 in intended paths, thus enhancing the light output efficiency.

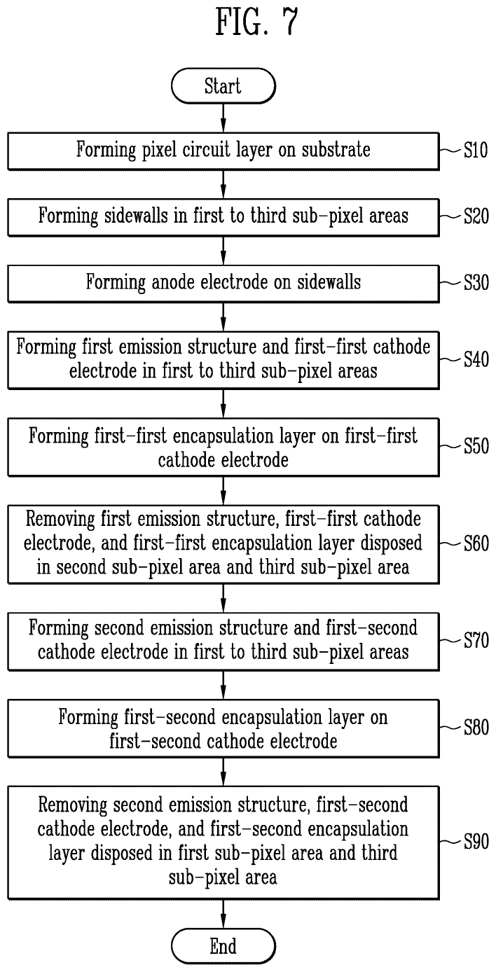

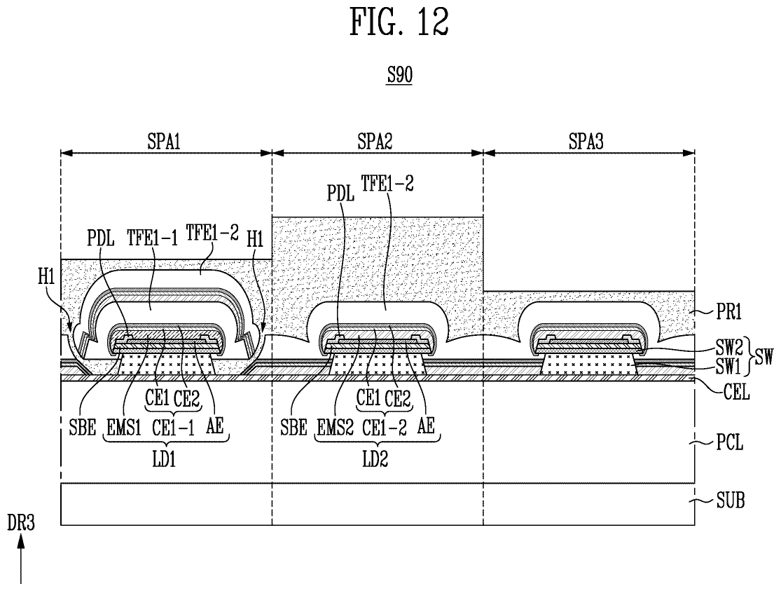

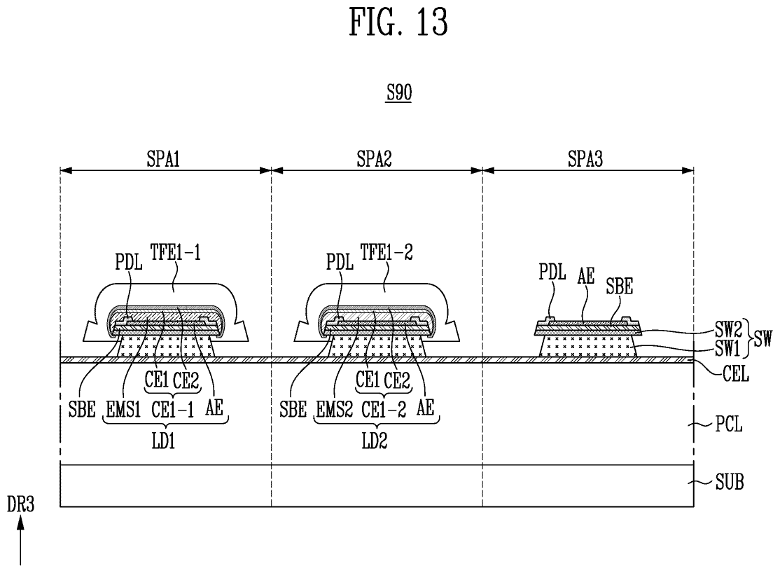

Hereinafter, a method of manufacturing the display device 100 according to an embodiment will be described with reference to FIGS. 7 to 15 in combination with FIG. 6. Any content that may overlap with the foregoing may be briefly explained or may not be repeated. In the following description, the first to third emission structures EMS1 to EMS3 are sequentially formed. However, the disclosure is not limited thereto. For example, the first light-emitting structure EMS1 may be formed after the third light-emitting structure EMS3 is formed.

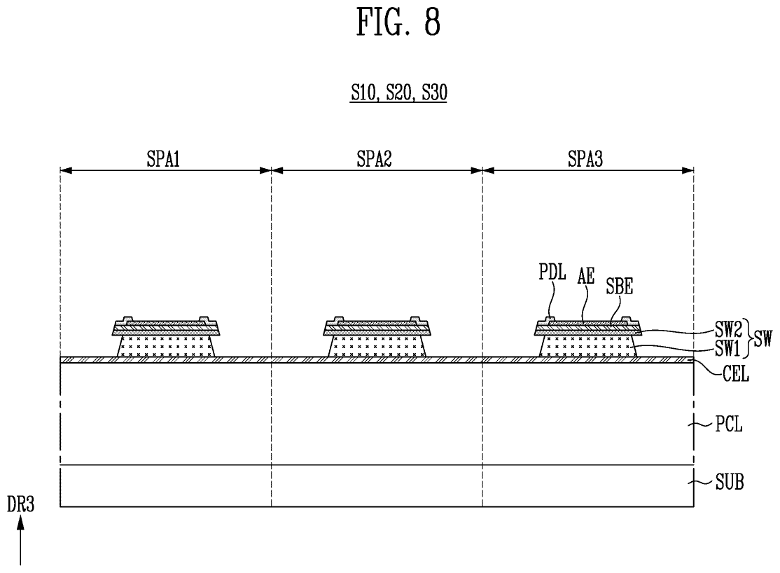

FIG. 7 is a flowchart illustrating a method of manufacturing the display device according to an embodiment. FIGS. 8 to 15 are schematic cross-sectional views of the method of manufacturing the display device according to an embodiment.

Referring to FIGS. 7 and 8, the method of manufacturing the display device 100 may include S10 forming a pixel circuit layer on a substrate, S20 forming sidewalls in first to third sub-pixel areas, and S30 forming an anode electrode on the sidewalls.

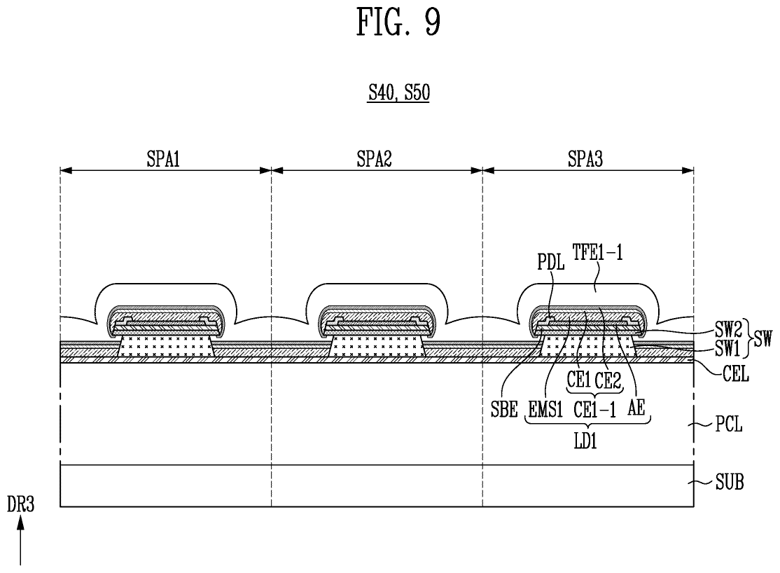

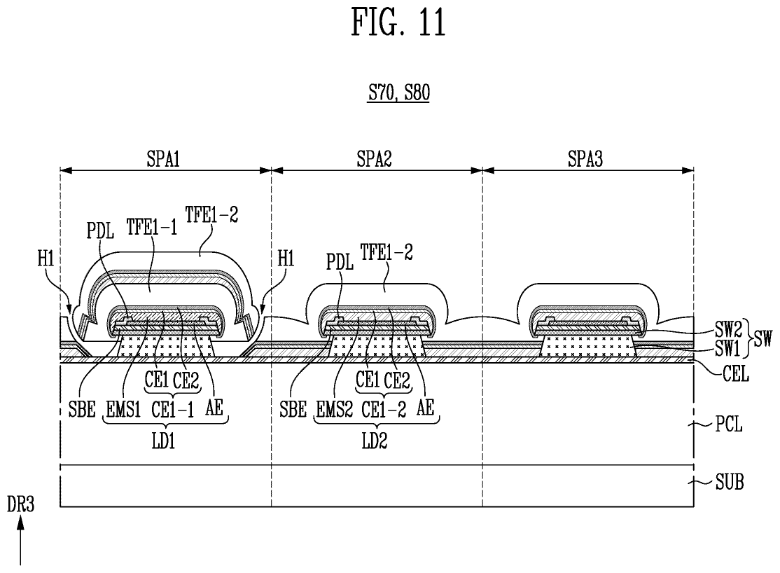

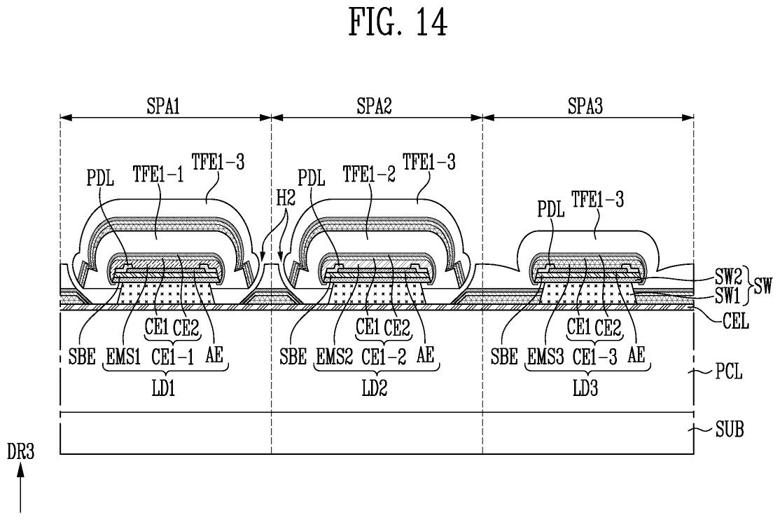

In the S10 forming the pixel circuit layer PCL on the substrate SUB, circuit elements (e.g., the transistors T_SP1 to T_SP3) may be patterned on the substrate SUB, and the pixel circuit layer PCL may be provided. The S10 forming the pixel circuit layer PCL on the substrate SUB may include a forming the metal layer CEL. The metal layer CEL may be a power supply wiring that applies a cathode voltage to each of a first-first cathode electrode CE1-1 (see FIG. 9), a first-second cathode electrode CE1-2 (see FIG. 11), and a first-third cathode electrode CE1-3 (see FIG. 14) to be formed after the S10 forming the pixel circuit layer PCL on the substrate SUB.

In an embodiment, a conductive layer (e.g., an electrically conductive layer), an insulating layer (e.g., an electrically insulating layer), and/or the like on the substrate SUB may be formed based on a general process for manufacturing a semiconductor device. For example, the conductive layer or the insulating layer on the substrate SUB may be formed through a photolithography process, may be etched by various suitable methods (e.g., wet etching, dry etching, and/or the like), and may be deposited by various suitable methods (e.g., sputtering, chemical vapor deposition, and/or the like). However, the disclosure is not limited to a specific example.

In the S20 forming sidewalls SW in the first to third sub-pixel areas SPA1 to SPA3, each sidewalls SW may be formed in the first to the third sub-pixel areas SPA1 to SPA3. Each of the sidewalls SW may include a first sidewall SW1 and a second sidewall SW2. The second sidewall SW2 may be formed to protrude further in the first direction DR1 and the second direction DR2 than the first sidewall SW1.

In an embodiment, in the S20 forming sidewalls SW in the first to third sub-pixel areas SPA1 to SPA3, the sidewalls SW may be formed to have a thickness of 400 nm to 600 nm.

In an embodiment, the method of manufacturing the display device 100 may further include forming sub-insulating layers SBE on the sidewalls SW. The sub-insulating layer SBE may be on the second sidewall SW2 and may be in contact with the second sidewall SW2.

In the S30 forming the anode electrode AE on the sidewalls SW, each of the anode electrodes AE may be formed in each of the first to third sub-pixel areas SPA1 to SPA3. The anode electrode AE is on the second sidewall SW2 and may overlap the second sidewall SW2. The anode electrode AE may be in contact with the sub-insulating layer SBE.

In an embodiment, the method of manufacturing the display device 100 may further include forming the pixel defining layer PDL on the anode electrode AE. The pixel defining layer PDL may be around or surround (or enclose) the edge of the anode electrode AE and may expose a portion of the anode electrode AE.

Referring to FIGS. 7 and 9, the method of manufacturing the display device 100 may include S40 forming a first emission structure EMS1 and a first-first cathode electrode CE1-1 in the first to third sub-pixel areas SPA1 to SPA3.

In S40, the first emission structure EMS1 and the first-first cathode electrode CE1-1 may be formed over the first to third sub-pixel areas SPA1 to SPA3. For example, the first emission structure EMS1 and the first-first cathode electrode CE1-1 may be formed on each of the sidewalls SW provided in each of the first to third sub-pixel areas SPA1 to SPA3, and may be formed over a boundary region of the first to the third sub-pixel areas SPA1 to SPA3. The first emission structure EMS1 and the first-first cathode electrode CE1-1 may overlap the first to third sub-pixel areas SPA1 to SPA3, respectively.

The first-first cathode electrode CE1-1 may have the same configuration as the aforementioned cathode electrode CE. For example, the first-first cathode electrode CE1-1 may include a first cathode electrode CE1 and a second cathode electrode CE2. Forming the first-first cathode electrode CE1-1 may include forming the first cathode electrode CE1 and forming the second cathode electrode CE2. The first-first cathode electrode CE1-1 may constitute a cathode electrode CE of the first light emitting element LD1 provided in the first sub-pixel area SPA1.

In S40, the first light emitting element LD1 may be formed, and the first light emitting element LD1 may also be provided in the first to third sub-pixel areas SPA1 to SPA3.

The method of manufacturing the display device 100 may further include S50 forming the first-first encapsulation layer TFE1-1 on the first-first cathode electrode CE1-1.

In S50, first-first encapsulation layer TFE1-1 may be formed over the first to third sub-pixel areas SPA1 to SPA3. For example, the first-first encapsulation layer TFE1-1 may overlap each of the first to third sub-pixel areas SPA1 to SPA3. The first-first encapsulation layer TFE1-1 may cover sidewalls SW provided in each of the first to third sub-pixel areas SPA1 to SPA3.

The top surface of first-first encapsulation layer TFE1-1 may have a step. For example, the top surface of a first portion of the first-first encapsulation layer TFE1-1 that overlaps with the sidewalls SW may be provided higher than the top surface of a second portion of the first-first encapsulation layer TFE1-1 that overlaps with the boundary region of the first to third sub-pixel areas SPA1 to SPA3.

In an embodiment, in the S50 forming the first-first encapsulation layer TFE1-1 on the first-first cathode electrode CE1-1, the first-first encapsulation layer TFE1-1 may be formed to have a thickness of 1.1 μm to 1.6 μm.

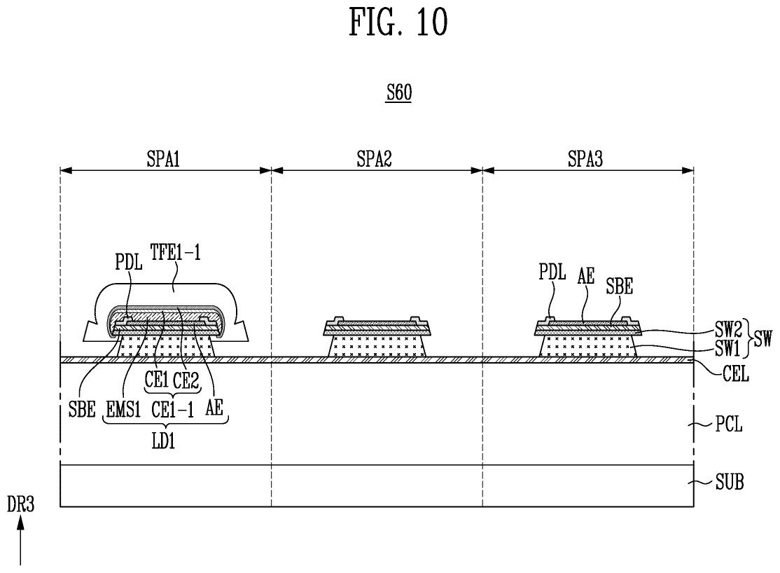

Referring to FIGS. 7 and 10, the method of manufacturing the display device 100 may further include S60 removing the first emission structure EMS1, the first-first cathode electrode CE1-1, and the first-first encapsulation layer TFE1-1 provided in the second sub-pixel area SPA2 and the third sub-pixel area SPA3.

In S60, the first emission structure EMS1, the first-first cathode electrode CE1-1, and the first-first encapsulation layer TFE1-1 provided (or that overlaps) in the second and third sub-pixel areas SPA2, SPA3 may be removed. In S60, the first light emitting structure EMS1, the first-first anode electrode CE1-1, and the first-first encapsulation layer TFE1-1 provided in the boundary region of the first to third sub-pixel areas SPA1 to SPA3 may be removed. In an embodiment, at least one selected from the first emission structure EMS1, the first-first cathode electrode CE1-1, and the first-first encapsulation layer TFE1-1 may be removed through a dry etching process.

A photoresist may be on the first-first encapsulation layer TFE1-1 to remove a portion of the first emission structure EMS1, the first-first cathode electrode CE1-1, and the first-first encapsulation layer TFE1-1. The photoresist may overlap the sidewall SW disposed in the first sub-pixel area SPA1. In an embodiment, the photoresist may be on the sidewall SW provided in the first sub-pixel area SPA1, and may not be provided in the second sub-pixel area SPA2 and the third sub-pixel area SPA3. In embodiments, the photoresist may be provided in the first to third sub-pixel areas SPA1 to SPA3, and the photoresist may have different thicknesses in one region. For example, the photoresist may have a thinner thickness in each of the second sub-pixel area SPA2 and the third sub-pixel area SPA3 than in the first sub-pixel area SPA1.

The photoresist may be removed after S60.

In S60, the first emission structure EMS1, the first-first cathode electrode CE1-1, and the first-first encapsulation layer TFE1-1 that remain after being removed may overlap the first sub-pixel area SPA1 in a plan view, and may not overlap the second sub-pixel area SPA2 and the third sub-pixel area SPA3. The first emission structure EMS1, the first-first cathode electrode CE1-1, and the first-first encapsulation layer TFE1-1 after S60 may be provided in the first sub-pixel area SPA1, and may not be provided in the second and third sub-pixel areas SPA2 and SPA3.

In S60, the top surface of the remaining first-first encapsulation layer TFE1-1 may have a step. In an embodiment, the side surface of the first-first encapsulation layer TFE1-1 may be inclined.

In S60, the metal layer CEL may be exposed. The metal layer CEL may be spaced apart from the bottom surface of the first-first encapsulation layer TFE1-1 and may not be in contact with the bottom surface of the first-first encapsulation layer TFE1-1. For example, an empty space may be formed between the bottom surface of the first-first encapsulation layer TFE1-1 and the metal layer CEL.

Referring to FIGS. 7 and 11, the method of manufacturing the display device 100 may further include S70 forming the second emission structure EMS2 and the first-second cathode electrode CE1-2 in the first to third sub-pixel areas SPA1 to SPA3, and S80 forming the first-second encapsulation layer TFE1-2 on the first-second cathode electrode CE1-2.

In S70, the second emission structure EMS2 and the first-second cathode electrode CE1-2 may be formed over the first to third sub-pixel areas SPA1 to SPA3. For example, the second emission structure EMS2 and the first-second cathode electrode CE1-2 may be formed on each of the sidewalls SW provided in each of the first to third sub-pixel areas SPA1 to SPA3, and may be formed over the boundary region of the first to the third sub-pixel areas SPA1 to SPA3. The second emission structure EMS2 and the first-second cathode electrode CE1-2 may overlap the first to third sub-pixel areas SPA1 to SPA3, respectively.

The first-second cathode electrode CE1-2 may have the same configuration as the aforementioned cathode electrode CE. For example, the first-second cathode electrode CE1-2 may include a first cathode electrode CE1 and a second cathode electrode CE2. Forming the first-second cathode electrode CE1-2 may include forming the first cathode electrode CE1 and forming the second cathode electrode CE2. The first-second cathode electrode CE1-2 may constitute a cathode electrode CE of the second light emitting element LD2 provided in the second sub-pixel area SPA2.

In S70, the second light emitting element LD2 may be formed, and the second light emitting element LD2 may be provided in the second sub-pixel area SPA2 and the third sub-pixel area SPA3.

In S80, the first-second encapsulation layer TFE1-2 may be formed over the first to third sub-pixel areas SPA1 to SPA3. For example, the first-second encapsulation layer TFE1-2 may overlap each of the first to third sub-pixel areas SPA1 to SPA3. The first-second encapsulation layer TFE1-2 may cover sidewalls SW provided in each of the first to third sub-pixel areas SPA1 to SPA3.

The first-second encapsulation layer TFE1-2 is formed over the first to third sub-pixel areas SPA1 to SPA3, but may be formed discontinuously in some regions. For example, the first-second encapsulation layer TFE1-2 may have a structure that is not connected in some areas. For example, the first-second encapsulation layer TFE1-2 may include the opening H1, and the first-second encapsulation layer TFE1-2 have a disconnected structure in a region including the opening H1.

The opening H1 of the first-second encapsulation layer TFE1-2 may overlap the first sub-pixel area SPA1, and may not overlap the second sub-pixel area SPA2 and the third sub-pixel area SPA3. The opening H1 of the first-second encapsulation layer TFE1-2 may be adjacent to the edge of the first-first encapsulation layer TFE 1-1. For example, the opening H1 of the first-second encapsulation layer TFE1-2 may be next to the edge of the first-first encapsulation layer TFE1-1. For example, the opening H1 of the first-second encapsulation layer TFE1-2 may be around or surround the edge of the first-first encapsulation layer TFE 1-1 in a plan view.

In an embodiment, the opening H1 of the first-second encapsulation layer TFE1-2 may be formed to be inclined, but the disclosure is not limited thereto.

The top surface of the first-second encapsulation layer TFE1-2 may have a step. For example, the top surface of a first portion of the first-second encapsulation layer TFE1-2 that overlaps with the sidewalls SW may be higher than the top surface of a second portion of the first-second encapsulation layer TFE1-2 that overlaps with the boundary region of the first to third sub-pixel areas SPA1 to SPA3.

In an embodiment, in S80, the first-second encapsulation layers TFE1-2 may be formed to have a thickness of 1.1 μm to 1.6 μm.

Referring to FIGS. 7, 12, and 13, the method of manufacturing the display device 100 may further include S90 removing the second emission structure EMS2, the first-second cathode electrode CE1-2, and the first-second encapsulation layer TFE1-2 provided in the first sub-pixel area SPA1 and the third sub-pixel area SPA3.

In S90, the second emission structure EMS2, the first-second cathode electrode CE1-2, and the first-second encapsulation layer TFE1-2 provided (or that overlaps) in the first and third sub-pixel areas SPA1, SPA3 may be removed. In S90, the second emission structure EMS2, the first-second cathode electrode CE1-2, and the first-second encapsulation layer TFE1-2 provided in the boundary region of the first to third sub-pixel areas SPA1 to SPA3 may be removed. In an embodiment, at least one selected from the second emission structure EMS2, the first-second cathode electrode CE1-2, and the first-second encapsulation layer TFE1-2 may be removed through a dry etching process.

A first photoresist PR1 may be provided (or formed) on the first-second encapsulation layer TFE1-2 to remove a portion of the second emission structure EMS2, the first-second cathode electrode CE1-2, and the first-second encapsulation layer TFE1-2. In an embodiment, the first photoresist PR1 is provided in the first to third sub-pixel areas SPA1 to SPA3, and the first photoresist PR1 may have different thicknesses in one region. For example, the first photoresist PR1 may have a thickness smaller than that of the second sub-pixel area SPA2 in each of the first sub-pixel area SPA1 and the third sub-pixel area SPA3. In embodiments, the first photoresist PR1 may be on the sidewall SW provided in the second sub-pixel area SPA2 to overlap with the sidewall SW provided in the second subpixel area SPA2, and may not be provided in the first sub-pixel area SPA1 and the third sub-pixel area SPA3.

In the providing the first photoresist PR1, at least a portion of the first photoresist PR1 may flow into the opening H1 of the first-second encapsulation layer TFE1-2. For example, in the disposing the first photoresist PR1, at least the portion of the first photoresist PR1 fills the opening H1 and may flow under the first-first encapsulation layer TFE1-1. At least the portion of the first photoresist PR1 that has flowed under the first-first encapsulation layer TFE1-1 may be under the first-first encapsulation layer TFE1-1, and may be in contact with the bottom surface of the first-first encapsulation layer TFE1-1. At least the portion of the first photoresist PR1 may be in contact with the metal layer CEL.

The first photoresist PR1 may be removed after S90.

In S90, the second emission structure EMS2, the first-second cathode electrode CE1-2, and the first-second encapsulation layer TFE1-2 that remain after being removed may overlap the second sub-pixel area SPA2 in a plan view, and may not overlap the first sub-pixel area SPA1 and the third sub-pixel area SPA3. The second emission structure EMS2, the first-second cathode electrode CE1-2, and the first-second encapsulation layer TFE1-2 after S90 may be provided in the second sub-pixel area SPA2, and may not be provided in the first and third sub-pixel areas SPA1 and SPA3.

In S90, the top surface of the remaining first-second encapsulation layer TFE1-2 may have a step. In an embodiment, the side surface of the first-second encapsulation layer TFE1-2 may be inclined.

In S90, the metal layer CEL may be exposed. The metal layer CEL may be spaced apart from the bottom surface of the first-second encapsulation layer TFE1-2 and may not be in contact with the bottom surface of the first-second encapsulation layer TFE1-2. For example, an empty space may be formed between the bottom surface of the first-second encapsulation layer TFE1-2 and the metal layer CEL.

According to the manufacturing method of the display device 100 according to embodiments of the disclosure, the first-second encapsulation layer TFE1-2 may include the opening H1 and the first photoresist PR1 may flow into the opening H1 of the first-second encapsulation layer TFE1-2. At least the portion of the first photoresist PR1 may be under the first-first encapsulation layer TFE1-1, so that the risk that the first-first encapsulation layer TFE1-1 is peeled off when at least one of the second emission structure EMS2, the first-second cathode electrodes CE1-2, and the first-second encapsulation layer TFE1-2 is dry-etched may be reduced.

For example, at least the portion of the first photoresist PR1 may protect the bottom surface of the first-first encapsulation layer TFE1-1, and may reduce the risk of the first-first encapsulation layer TFE1-1 being damaged and peeled off. The risk of the first-first encapsulation layer TFE1-1 being peeled off is reduced, so that the risk of foreign matter penetrating into the first light emitting element LD1 may be reduced, and the reliability of the display device 100 may be increased.

Referring to FIG. 14, the method of manufacturing the display device 100 may further include forming the third emission structure EMS3 and the first-third cathode electrode CE1-3 in the first to third sub-pixel areas SPA1 to SPA3, and forming the first-third encapsulation layer TFE1-3 on the first-third cathode electrode CE1-3.

In the forming the third emission structure EMS3 and the first-third cathode electrode CE1-3 in the first to third sub-pixel areas SPA1 to SPA, the third emission structure EMS3 and the first-third cathode electrode CE1-3 may be formed over the first to third sub-pixel areas SPA1 to SPA3. For example, the third emission structure EMS3 and the first-third cathode electrode CE1-3 may be formed on each of the sidewalls SW provided in each of the first to third sub-pixel areas SPA1 to SPA3, and may be formed over the boundary region of the first to the third sub-pixel areas SPA1 to SPA3. The third emission structure EMS3 and the first-third cathode electrode CE1-3 may overlap the first to third sub-pixel areas SPA1 to SPA3, respectively.

The first-third cathode electrode CE1-3 may have the same or substantially the same configuration as the aforementioned cathode electrode CE. For example, the first-third cathode electrode CE1-3 may include a first cathode electrode CE1 and a second cathode electrode CE2. Forming the first-third cathode electrode CE1-3 may include forming the first cathode electrode CE1 and forming the second cathode electrode CE2. The first-third cathode electrode CE1-3 may constitute a cathode electrode CE of the third light emitting element LD3 provided in the third sub-pixel area SPA3.

In the forming the third emission structure EMS3 and the first-third cathode electrode CE1-3 in the first to third sub-pixel areas SPA1 to SPA3, the third light emitting element LD3 may be formed, and the third light emitting element LD3 may be provided in the third sub-pixel area SPA3.

In the forming the first-third encapsulation layer TFE1-3 on the first-third cathode electrode CE1-3, the first-third encapsulation layer TFE1-3 may be formed over the first to third sub-pixel areas SPA1 to SPA3. For example, the first-third encapsulation layer TFE1-3 may overlap each of the first to third sub-pixel areas SPA1 to SPA3. The first-third encapsulation layer TFE1-3 may cover sidewalls SW provided in each of the first to third sub-pixel areas SPA1 to SPA3.

The first-third encapsulation layer TFE1-3 is formed over the first to third sub-pixel areas SPA1 to SPA3, but may be formed discontinuously in some regions. For example, the first-third encapsulation layer TFE1-3 may have a structure that is not connected in some areas. For example, the first-third encapsulation layer TFE1-3 may include the opening H2, and the first-third encapsulation layer TFE1-3 have a disconnected structure in a region including the opening H2.

The opening H2 of the first-third encapsulation layer TFE1-3 may overlap the first sub-pixel area SPA1 and the second sub-pixel area SPA2, and may not overlap the third sub-pixel area SPA3. The opening H2 of the first-third encapsulation layer TFE1-3 may be adjacent to the edge of each of the first-first encapsulation layer TFE 1-1 and the first-second encapsulation layer TFE1-2. For example, the opening H2 of the first-third encapsulation layer TFE1-3 may be next to the edge of each of the first-first encapsulation layer TFE1-1 and the first-second encapsulation layer TFE1-2. For example, the opening H2 of the first-third encapsulation layer TFE1-3 may be around or surround the edge of each of the first-first encapsulation layer TFE1-1 and the first-second encapsulation layer TFE1-2 in a plan view.

In an embodiment, the opening H2 of the first-third encapsulation layer TFE1-3 may be formed to be inclined, but the disclosure is not limited thereto.

The top surface of the first-third encapsulation layer TFE1-3 may have a step. For example, the top surface of a first portion of the first-third encapsulation layer TFE1-3 that overlaps with the sidewalls SW may be higher than the top surface of a second portion of the first-third encapsulation layer TFE1-3 that overlaps with the boundary region of the first to third sub-pixel areas SPA1 to SPA3.

In an embodiment, in the forming the first-third encapsulation layer TFE1-3 on the first-third cathode electrode CE1-3, the first-third encapsulation layer TFE1-3 may be formed to have a thickness of 1.1 μm to 1.6 μm.

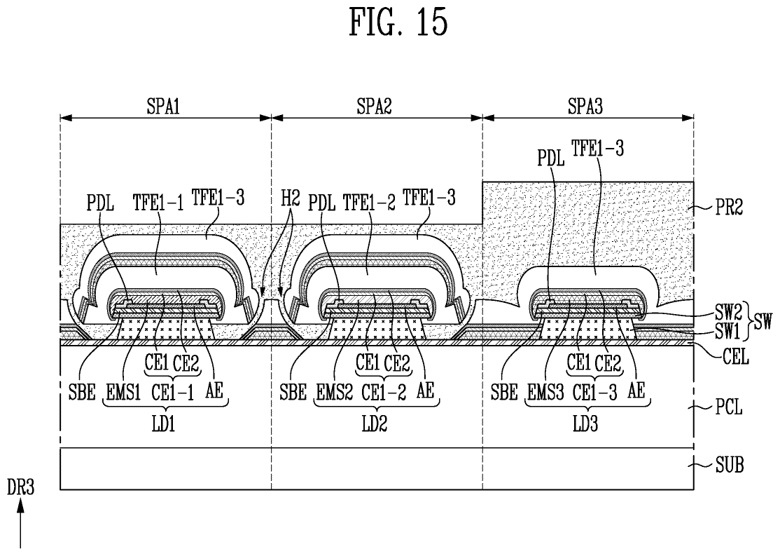

Referring to FIGS. 6 and 15, the method of manufacturing the display device 100 may further include removing the third emission structure EMS3, the first-third cathode electrode CE1-3, and the first-third encapsulation layer TFE1-3 provided in the first sub-pixel area SPA1 and the second sub-pixel area SPA2.

In the removing the third emission structure EMS3, the first-third cathode electrode CE1-3, and the first-third encapsulation layer TFE1-3 provided in the first sub-pixel area SPA1 and the second sub-pixel area SPA2, the third emission structure EMS3, the first-third cathode electrode CE1-3, and the first-third encapsulation layer TFE1-3 provided (or that overlaps) in the first and second sub-pixel areas SPA1, SPA2 may be removed. In the removing the third emission structure EMS3, the first-third cathode electrode CE1-3, and the first-third encapsulation layer TFE1-3 provided in the first sub-pixel area SPA1 and the second sub-pixel area SPA2, the third emission structure EMS3, the first-third cathode electrode CE1-3, and the first-third encapsulation layer TFE1-3 provided in the boundary region of the first to third sub-pixel areas SPA1 to SPA3 may be removed. In an embodiment, at least one selected from the third emission structure EMS3, the first-third cathode electrode CE1-3, and the first-third encapsulation layer TFE1-3 may be removed through a dry etching process.

A second photoresist PR2 may be provided (or formed) on the first-third encapsulation layer TFE1-3 to remove a portion of the third emission structure EMS3, the first-third cathode electrode CE1-3, and the first-third encapsulation layer TFE1-3. In an embodiment, the second photoresist PR2 is provided in the first to third sub-pixel areas SPA1 to SPA3, and the second photoresist PR2 may have different thicknesses in one region. For example, the second photoresist PR2 may have a thickness smaller than that of the third sub-pixel area SPA3 in each of the first sub-pixel area SPA1 and the second sub-pixel area SPA2. In embodiments, the second photoresist PR2 may be on the sidewall SW provided in the third sub-pixel area SPA3 to overlap with the sidewall SW provided in the third sub-pixel area SPA3, and may not be provided in the first sub-pixel area SPA1 and the second sub-pixel area SPA2.

In the provided the second photoresist PR2, at least a portion of the second photoresist PR2 may flow into the opening H2 of the first-third encapsulation layer TFE1-3. For example, in the providing the second photoresist PR2, at least the portion of the second photoresist PR2 fills the opening H2 and may flow under each of the first-first encapsulation layer TFE1-1 and the first-second encapsulation layer TFE1-2. At least the portion of the second photoresist PR2 that has flowed under each of the first-first encapsulation layer TFE1-1 and the first-second encapsulation layer TFE1-2 may be under each of the first-first encapsulation layer TFE1-1 and the first-second encapsulation layer TFE1-2, and may be in contact with the bottom surface of each of the first-first encapsulation layer TFE1-1 and the first-second encapsulation layer TFE1-2. At least the portion of the second photoresist PR2 may be in contact with the metal layer CEL.

The second photoresist PR2 may be removed after the removing the third emission structure EMS3, the first-third cathode electrode CE1-3, and the first-third encapsulation layer TFE1-3 provided in the first sub-pixel area SPA1 and the second sub-pixel area SPA2.

In the removing the third emission structure EMS3, the first-third cathode electrode CE1-3, and the first-third encapsulation layer TFE1-3 provided in the first sub-pixel area SPA1 and the second sub-pixel area SPA2, the third emission structure EMS3, the first-third cathode electrode CE1-3, and the first-third encapsulation layer TFE1-3 that remain after being removed may overlap the third sub-pixel area SPA3 in a plan view, and may not overlap the first sub-pixel area SPA1 and the second sub-pixel area SPA2. The third emission structure EMS3, the first-third cathode electrode CE1-3, and the first-third encapsulation layer TFE1-3 after the removing the third emission structure EMS3, the first-third cathode electrode CE1-3, and the first-third encapsulation layer TFE1-3 provided in the first sub-pixel area SPA1 and the second sub-pixel area SPA2 may be provided in the third sub-pixel area SPA3, and may not be provided in the first and second sub-pixel areas SPA1 and SPA2.

In the removing the second emission structure EMS2, the first-second cathode electrode CE1-2, and the first-second encapsulation layer TFE1-2 provided in the first sub-pixel area SPA1 and the third sub-pixel area SPA3, the top surface of the remaining first-second encapsulation layer TFE1-2 may have a step. In an embodiment, the side surface of the first-second encapsulation layer TFE1-2 may be inclined.

In the third emission structure EMS3, the first-third cathode electrode CE1-3, and the first-third encapsulation layer TFE1-3 provided in the first sub-pixel area SPA1 and the second sub-pixel area SPA2, the metal layer CEL may be exposed. The metal layer CEL may be spaced apart from the bottom surface of the first-third encapsulation layer TFE1-3 and may not be in contact with the bottom surface of the first-third encapsulation layer TFE1-3. For example, an empty space may be formed between the bottom surface of the first-third encapsulation layer TFE1-3 and the metal layer CEL.

According to the manufacturing method of the display device 100 according to embodiments of the disclosure, the first-third encapsulation layer TFE1-3 may include the opening H2 and the second photoresist PR2 may flow into the opening H2 of the first-third encapsulation layer TFE1-3. At least the portion of the first photoresist PR2 may be under the first-first encapsulation layer TFE1-1 and the first-second encapsulation layer TFE1-2, so that the risk of the first-first encapsulation layer TFE1-1 and the first-second encapsulation layer TFE1-2 being peeled off when at least one selected from the third emission structure EMS3, the first-third cathode electrode CE1-3, and the first-third encapsulation layer TFE1-3 is dry-etched may be reduced.

For example, at least the portion of the second photoresist PR2 may protect the bottom surfaces of the first-first encapsulation layer TFE1-1 and the first-second encapsulation layer TFE1-2, and may reduce the risk of the first-first encapsulation layer TFE1-1 and the first-second encapsulation layer TFE1-2 being damaged and peeled off. The risk of the first-first encapsulation layer TFE1-1 and the first-second encapsulation layer TFE1-2 being peeled off is reduced, so that the risk of foreign matter penetrating into the first light emitting element LD1 and the second light emitting element LD2 may be reduced, and the reliability of the display device 100 may be increased.

In an embodiment, when each of the first-first encapsulation layer TFE1-1, the first-second encapsulation layer TFE1-2, and the first-third encapsulation layer TFE-1-3 has the thickness of 1.1 μm to 1.6 μm, and the sidewall SW has the thickness of 400 nm to 600 nm, the amount of etching gas injected during dry etching may be reduced. Because the amount of etching gas is reduced, the risk of the first-first encapsulation layer TFE1-1 and the first-second encapsulation layer TFE1-2 being damaged when dry etching is performed may be reduced, and the reliability of the display device 100 may be further increased.

The display device 100 according to an embodiment is applicable to various suitable types or kinds of electronic devices. In an embodiment, an electronic device includes the above-described display device manufactured by the method of manufacturing the display device 100 and may further include other modules and/or devices having additional functions in addition to the display device.

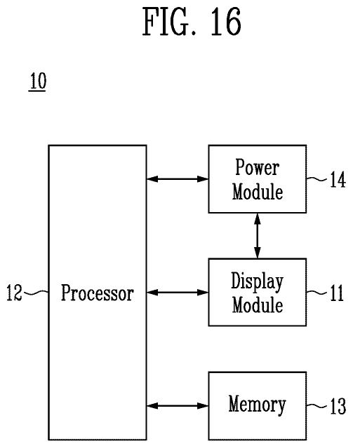

FIG. 16 is a block diagram of an electronic device according to an embodiment. Referring to FIG. 16, the electronic device 10 may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter and/or a battery device, and a power conversion module. The power conversion module converts power supplied by the power supply module and generates power to operate the electronic device 10.

At least one of the above-described components of the electronic device 10 may be included in the display device 100 according to embodiments as described above. In embodiments, in terms of functionality, some of the individual modules included in one module may be included in the display device 100 and others may be provided separately from the display device 100. For example, the display module 11 is included in the display device 100, whereas the processor 12, the memory 13, and the power module 14 are not included in the display device 100 and are instead provided separately in the electronic device 10.

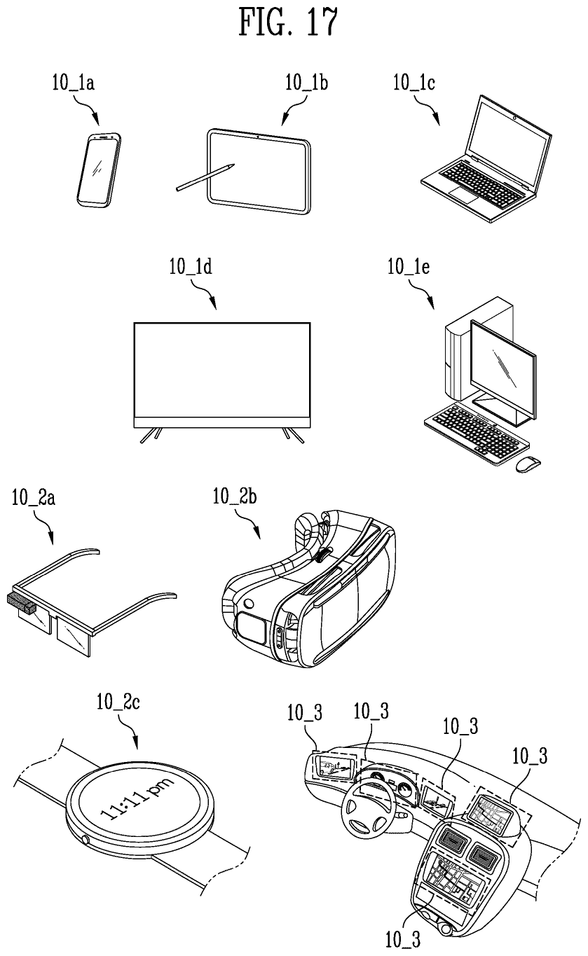

FIG. 17 shows schematic views of various suitable embodiments of an electronic device.

Referring to FIG. 17, various suitable types or kinds of electronic devices to which embodiments of a display device are applied may include an electronic device to display images such as a smartphone 10_1a, a tablet PC 10_1b, a laptop computer 10_1c, a television (TV) 10_1d, and/or a desktop monitor 10_1e, a wearable electronic device including a display module such as smart glasses 10_2a, a head-mounted display (HMD) 10_2b, and/or a smart watch 10_2c, and/or an automotive electronic device 10_3 including a display module such as a center information display (CID) provided at the instrument cluster, the center fascia, and/or the dashboard of a vehicle, and/or a room mirror display.

An embodiment of the disclosure may provide a display device having improved resolution and reliability, and a method of manufacturing the display device.

An embodiment of the disclosure may provide an electronic device including the display device having improved resolution and reliability.

The effects of the disclosure are not limited by the foregoing, and other various suitable effects are included within the spirit and scope of this disclosure.

While various example embodiments have been described above, those skilled in the art will appreciate that various suitable modifications, additions and substitutions are possible, without departing from the scope and spirit of the disclosure.

Therefore, the embodiments disclosed in this specification are only for illustrative purposes rather than limiting the technical spirit of the disclosure. The scope of the disclosure must be defined by the accompanying claims, and equivalents thereof.

What is claimed is:

1. A method of manufacturing a display device, comprising:
forming sidewalls in first to third sub-pixel areas;
forming anode electrodes on the sidewalls;
forming a first emission structure and a first-first cathode electrode in the first to third sub-pixel areas;
forming a first-first encapsulation layer on the first-first cathode electrode;
removing the first emission structure, the first-first cathode electrode, and the first-first encapsulation layer provided in the second sub-pixel area and the third sub-pixel area;
forming a second emission structure and a first-second cathode electrode in the first to third sub-pixel areas; and
forming a first-second encapsulation layer on the first-second cathode electrode,
wherein the first-second encapsulation layer is formed discontinuously.

2. The method according to claim 1, wherein the first-second encapsulation layer formed in forming the first-second encapsulation layer:
is formed in the first to third sub-pixel areas, and
comprises an opening.

3. The method according to claim 2,
wherein the opening is provided in the first sub-pixel area.

4. The method according to claim 2, wherein the first-first encapsulation layer remaining after removal in removing the first-first encapsulation layer:
overlaps the first sub-pixel area in a plan view, and
does not overlap the second sub-pixel area and the third sub-pixel area in the plan view.

5. The method according to claim 4, wherein the opening is adjacent to an edge of the first-first encapsulation layer remaining after removal in removing the first-first encapsulation layer.

6. The method according to claim 4, wherein the opening surrounds an edge of the first-first encapsulation layer remaining after removal in removing the first-first encapsulation layer, in the plan view.

7. The method according to claim 2, further comprising:
removing the second emission structure, the first-second cathode electrode, and the first-second encapsulation layer provided in the first sub-pixel area and the third sub-pixel area, comprising providing a first photoresist on the first-second encapsulation layer,
wherein at least a portion of the first photoresist flows into the opening.

8. The method according to claim 7, wherein at least the portion of the first photoresist is under the first-first encapsulation layer in the first sub-pixel area.

9. The method according to claim 7, wherein at least the portion of the first photoresist is in contact with a bottom surface of the first-first encapsulation layer in the first sub-pixel area.

10. The method according to claim 7, further comprising:
forming a pixel circuit layer on a substrate, comprising forming a power supply wiring for applying a cathode voltage to the first-first cathode electrode,
wherein at least the portion of the first photoresist is in contact with the power wiring.

11. The method according to claim 7, wherein at least one selected from the second emission structure, the first-second cathode electrode, and the first-second encapsulation layer is removed through dry etching in removing the second emission structure, the first-second cathode electrode, and the first-second encapsulation layer.

12. The method according to claim 1, wherein each of the sidewalls comprises:
a first sidewall; and
a second sidewall on the first sidewall and having a larger width than the first sidewall.

13. The method according to claim 12, wherein the first sidewall and the second sidewall comprise a conductive material.

14. The method according to claim 13,
wherein each of the anode electrodes overlaps each of the sidewalls, and
wherein the first emission structure is in contact with a side surface of the second sidewall.

15. The method according to claim 13, wherein forming the first-first cathode electrode comprises:
forming a first cathode electrode; and
forming a second cathode electrode on the first cathode electrode,
wherein the second cathode electrode is in contact with a bottom surface of the second sidewall.

16. A display device, comprising:
a pixel circuit layer on a substrate;
a sidewall on the pixel circuit layer;
a first light emitting element on the sidewall; and
a first-first encapsulation layer on the first light emitting element,
wherein the sidewall has a thickness of 400 nm to 600 nm,
wherein the first-first encapsulation layer has a thickness of 1.1 μm to 1.6 μm.

17. The display device according to claim 16, wherein the sidewall comprises:
a first sidewall; and
a second sidewall on the first sidewall and having a larger width than the first sidewall,
wherein the first light emitting element overlaps the sidewall in a plan view.

18. The display device according to claim 17, wherein the first light emitting element comprises:
an anode electrode on the second sidewall;
a first emission structure on the anode electrode;
a first cathode electrode on the first emission structure; and
a second cathode electrode on the first cathode electrode,
wherein the second cathode electrode is in contact with a bottom surface of the second sidewall.

19. An electronic device comprising a display device, wherein the display device is manufactured by a method of manufacturing the display device, the method comprising:
forming sidewalls in first to third sub-pixel areas;
forming anode electrodes on the sidewalls;
forming a first emission structure and a first-first cathode electrode in the first to third sub-pixel areas;
forming a first-first encapsulation layer on the first-first cathode electrode;
removing the first emission structure, the first-first cathode electrode, and the first-first encapsulation layer provided in the second sub-pixel area and the third sub-pixel area;
forming a second emission structure and a first-second cathode electrode in the first to third sub-pixel areas; and
forming a first-second encapsulation layer on the first-second cathode electrode,
wherein the first-second encapsulation layer is formed discontinuously.

20. The electronic device according to claim 19, wherein the method further comprises:
removing the second emission structure, the first-second cathode electrode, and the first-second encapsulation layer provided in the first sub-pixel area and the third sub-pixel area,
wherein the first-second encapsulation layer formed in forming the first-second encapsulation layer:
is formed in the first to third sub-pixel areas, and
comprises an opening,
wherein removing the second emission structure, the first-second cathode electrode, and the first-second encapsulation layer comprises providing a first photoresist on the first-second encapsulation layer,
wherein at least a portion of the first photoresist flows into the opening.
